(19) United States
(12) Patent Application Publication
(10) Pub. No.: US 2005/0208907 A1
(43) Pub. Date: Sep. 22, 2005

(54) Detecting and maintaining linearity in a power amplifier system through envelope power comparisons

(76) Inventors: Ryo Yamazaki, Suwanee, GA (US); William Noellert, Atlanta, GA (US); Stephen Pratt, Cumming, GA (US)

Correspondence Address: SMITH FROHWEIN TEMPEL GREENLEE BLAHA, LLC, P.O. BOX 88148, ATLANTA, GA, 30356, US

(21) Appl. No.: 10/803,763

(22) Filed: Mar. 18, 2004

(51) Int. Cl. H04B 1/04; H01Q 11/12; H03F 3/217

(52) U.S. Cl. 455/126

(57) ABSTRACT

Small portable communication devices that support multiple modulation techniques cannot gain the benefits of using an isolator at the output of a power amplifier to provide stability in the load impedance. However, for communication devices that include amplitude modulation schemes, maintaining linear operation of the power amplifier is still required. In the presence of unstable load impedance, this can be a difficult task. As a solution, the linearity of the power amplifier is detected by comparing the envelope of the output signal with the base band signal used to modulate the output signal. If the envelopes are similar, then the power amplifier may be operating in the linear region. When the linearity of the power amplifier degrades, there is an increase in the difference between the envelopes. By adjusting the power level of the input signal to the power amplifier when the envelope difference appears, linearity of the power amplifier is maintained.

### CROSS-REFERENCE TO RELATED APPLICATIONS

This application is related to U.S. patent application No. ______ entitled “DETECTING AND MAINTAINING LINEARITY IN A POWER AMPLIFIER SYSTEM THROUGH COMPARING PEAK AND RMS POWER LEVELS” filed on the same date at this application and commonly assigned to the assignee of this application, which application is incorporated herein by reference in its entirety.

### TECHNICAL FIELD

The present invention is directed towards radio frequency transmission technology and, more specifically, towards a technique to detect and maintain linearity in a power amplifier for transmission systems that require linearity but do not have a stable output impedance or are susceptible to other conditions that can result in non-linear transmission.

### BACKGROUND

Cellular telephone technology has greatly advanced since its inception in the early 80's. Today, several cellular technologies are deployed throughout the world. One of the more prominent of the cellular technologies is the Global System for Mobile communication (GSM). GSM is a digital cellular communications system that was initially introduced in the European market but, it has gained widespread acceptance throughout the world. It was designed to be compatible with ISDN systems and the services provided by GSM are a subset of the standard ISDN services (speech is the most basic). Another advancement in cellular technology includes the General Packet Radio Service (GPRS) which is a packet based air interface that is overlaid on the existing circuit switched GSM network. GPRS is a non-voice value added service that allows information to be sent and received across a mobile telephone network.

The operational components of a GSM cellular system include mobile stations, base stations, and the network subsystem. The mobile stations are the small, hand-held telephones that are carried by subscribers. The base station controls the radio link with the mobile stations and the network subsystem performs the switching of calls between the mobile and other fixed or mobile network users. Because multiple cellular systems exist in the world, some mobile stations support more than one technology. Such mobile stations are typically referred to as “world phones” meaning that they can be used on a variety of different cellular systems around the world.

Various cellular technologies utilize different modulation schemes. For instance, the GSM transmission technology utilizes the Gaussian Minimum Shift Keying form of modulation (GMSK). In this modulation scheme, the phase of the carrier is instantaneously varied by the modulating signal. Some of the important characteristics of GMSK modulation are that the output signal has a constant envelope, a relatively narrow bandwidth and a coherent detection capability. However, the most important characteristic of these characteristics is the constant envelope. Signals that have a constant envelope are more immune to noise than signals that have varying amplitudes.

In addition, because GMSK modulation does not include amplitude components, a purely GMSK transmitter does not require the use of a linear power amplifier. This is advantageous because when amplifiers are operating in the non-linear region, they typically deliver much higher efficiencies than when they are operating in the linear region.

GPRS also uses GMSK in modulating the data being transmitted through the cellular network. The modulation schemes for both GSM and GPRS result in a transmission rate of 271 ksps (kilo-symbols-per second) at a 1-bit/symbol rate. To utilize the bandwidth more efficiently, Enhanced GPRS (or EGPRS) was introduced. Using EGPRS, the symbol rate is still 271 ksps but, rather than 1-bit per symbol, 3-bits per symbol are utilized thereby increasing the bit rate to 813 kbps. To accomplish this, a more efficient modulation scheme called 3π/8 8PSK is utilized. As previously mentioned, GMSK modulation has phase components and does not include amplitude components. However, 3π/8 8PSK modulation contains both phase and amplitude information and thus, requires a linear power amplifier to ensure that the amplitude information is not distorted during amplification.

Thus, in a mobile station that supports both GSM and EGPRS, it is evident that linearity in the power amplifier must be maintained. This is also true in most any multi-technology mobile station that includes both phase and amplitude information in the modulated signal. When the linearity of the power amplifier in such a mobile station is compromised, the required operating specifications for parameters such as adjacent-channel power ratio (ACPR) and error vector magnitude (EVM) can be violated.

Those skilled in the art will be aware that several factors operate against maintaining linearity in a power amplifier. These factors include, among other things, the operating temperature, the level of the supply voltage and the load impedance. For instance, with regards to the load impedance, the antenna of a mobile station can present a mismatch of up to a 10:1 voltage standing wave ratio. Traditionally, isolators have been used at the output of a power amplifier to present the power amplifier with a matched load impedance. However, today's mobile stations must be smaller, less expensive and support multiple frequency bands and transmission technologies. Because isolators are typically large, expensive and support only narrow bandwidths (which requires the use of multiple large and expensive isolators in multi-band phones) it is no longer practical to use an isolator. Thus, there is a need in the art for a method to maintain linearity in a power amplifier without the use of an isolator. In addition, there is a need in the art for a method to detect degradation in the linearity of a power amplifier and make adjustments to maintain linearity. There is also a need in the art for a method to detect non-linearity in a power amplifier when modulation schemes that require linearity are being used but to ignore such restraints when linearity is not required.

### SUMMARY OF THE INVENTION

The present invention provides a solution to the deficiencies in the current art by providing a technique to detect degradations in the linearity of a power amplifier and adjust the power level of the input signal to the power amplifier if degradations in the linearity of the power amplifier are detected. More specifically, the present invention operates to detect the output signal from a power amplifier. The envelope of the output signal is then compared to the envelope of the base band signal that was originally used to modulate the output signal. When the linearity of the power amplifier begins to degrade, the differences between the envelope of the output signal and the base band signal will become more pronounced. When degradation in the linearity of the power amplifier is detected, the power level of the signal being input to the power amplifier can be reduced to restore operation in the linear region. Thus, the present invention operates to detect linearity in the operation of a power amplifier and to maintain linearity in the operation of the power amplifier. Advantageously, this aspect of the present invention allows the power amplifier bias to be lowered and thereby improve the efficiency of the power amplifier.

### BRIEF DESCRIPTION OF THE DRAWINGS

FIG. 1A is a circuit diagram illustrating an exemplary embodiment of the present invention using a polar modulator.

FIG. 1B is a circuit diagram illustrating an exemplary embodiment of the present invention using a quadrature modulator.

FIGS. 2A-C are timing diagrams illustrating the relationship of the base band signal and the detected output signal when the power amplifier is operating in the linear range.

FIGS. 2D-2F are timing diagrams illustrating the relationship of the base band signal and the detected output signal when the power amplifier is not operating in the linear range.

FIGS. 3A-3B are flow diagrams illustrating the operations of the present invention.

FIG. 4 is a circuit diagram illustrating the incorporation of temperature and voltage compensation into present invention.

### DETAILED DESCRIPTION

The present invention provides a solution to the above-describe problems and needs in the art. The present invention includes a method and circuit for detecting the linearity of a power amplifier system, and maintaining linearity within the power amplifier system. One advantage of the invention is that the efficiency of the power amplifier can be improved by allowing the bias of the power amplifier to be lowered. More specifically, several factors, such as the operating temperature, the level of the supply voltage and the load impedance, operate to destroy linearity in a power amplifier. EVM is used to measure the modulation quality of a 3π/8 8PSK modulated signal and when the above-listed conditions are present, the amplitude error dominates the total EVM. AM to PM distortion affects the phase component of the 3π/8 8PSK modulated signal at the power amplifier output, but has minimal affect to the overall EVM and can be ignored when trying to determine the linearity within the power amplifier. By monitoring the amplitude envelope (AM modulation) of the power amplifier output, it is possible to determine the linearity of the power amplifier. The present invention operates to measure linearity by using a detector at the output of the power amplifier to measure the amplitude envelope and then compares the amplitude envelope against the known envelope signal. Based on the difference in the characteristics between the two amplitude envelopes, the degradation in linearity is calculated and based on this calculation, it is determined how much input power should be backed off to the power amplifier to restore linearity.

Now turning to the drawings in which like numerals and references refer to like elements throughout the several views, various aspects and embodiments of the present invention are described.

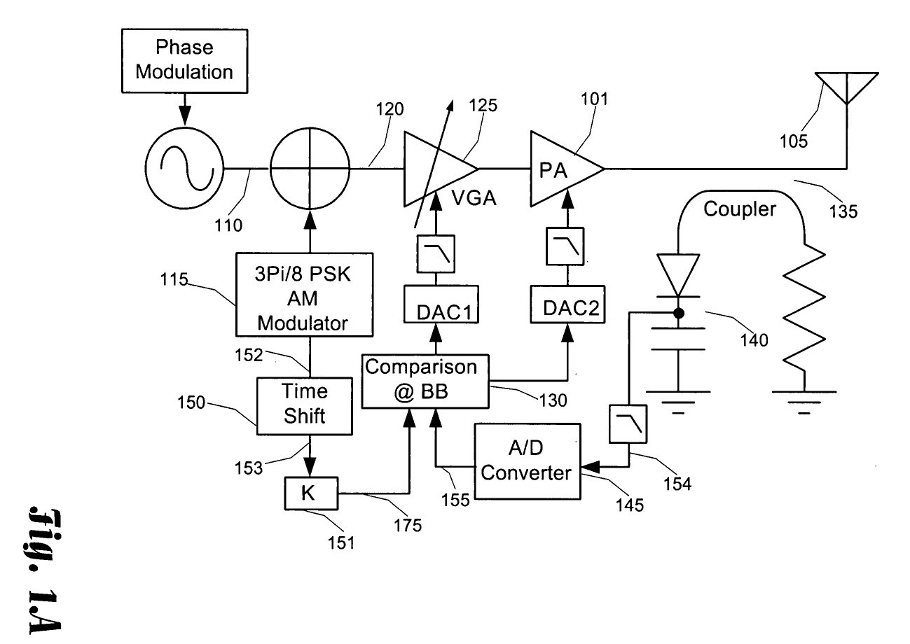

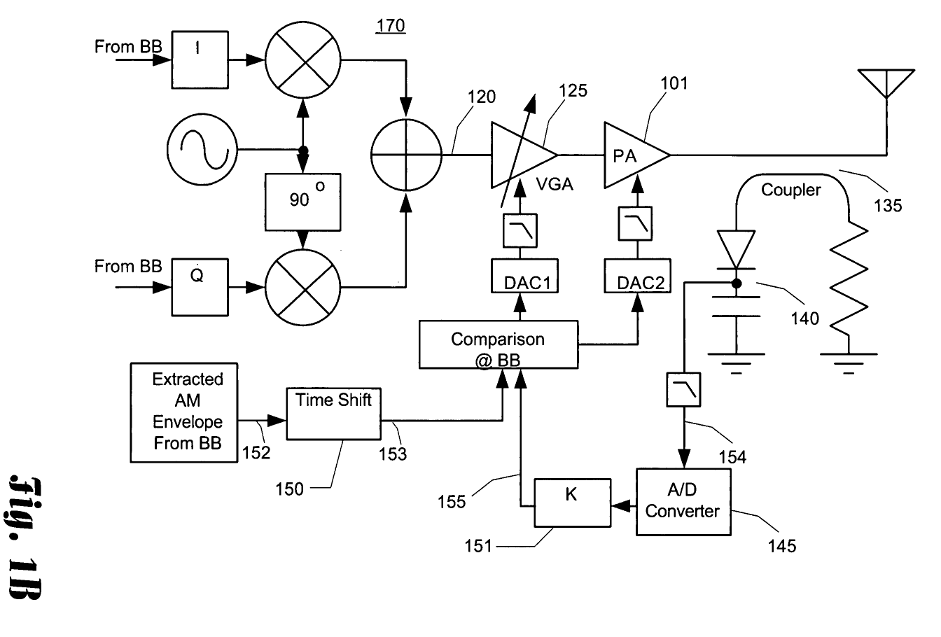

FIG. 1A is a circuit diagram illustrating an exemplary embodiment of the present invention. The circuit includes a power amplifier 101 that is used to amplify a modulated signal for transmission to the antenna 105. The amplified signal is a combination of a phase modulated signal at point 110 further modulated by an amplitude modulated (AM) envelope 115 to create a RF modulated signal (3π/8 8PSK) at point 120. The RF modulated signal at point 120 is then amplified through adjustable amplifier or variable gain amplifier 125 prior to being provided to the power amplifier 101. The AM envelope, otherwise termed as the base band signal 152, is also fed into a processor 130. Before the base band signal 152 is provided to the processor 130, it can be time shifted by passing it through time shift function 150 and scaled by passing it through scalar 151. It should be understood that the time shift function 150 and the scalar 151, although shown separate from the processor 130 can be integrated into the processor 130 and can operate in conjunction with the comparison to the detected signal 155 also. In addition, the scalar function could be applied to the detected signal 154 rather than the base band signal 152. Obviously, the scalar would operate differently if applied to the detected signal 154 rather than the base band signal 152. In either case, the goal is to align the signals in both time and scale.

The output of the power amplifier 101 is fed directly to the antenna 105 for transmission. A coupler 135 is used to sense the output of the power amplifier and the output signal is detected across voltage detector 140. The detected voltage 154 is provided to analog-to-digital converter 145 and the detected digitized signal 155 is then provided to the processor 130.

The processor 130 receives both the base band signal 152 and the detected digitized signal 155. Typically, the timing alignment of the base band signal 152 and the detected digitized signal 155 will not be the same and thus the signals will be skewed. Time shift circuit 150 can be used to help align these signals but it is not required and in addition, it may not be totally accurate. The processor 130 operates to compare the base band signal 152 with the detected digitized signal 155. This comparison process may include identifying the timing differences between the two signals and accounting for the skewing. Ultimately, the processor 130 will identify the timing differences between the two signals and conduct a comparison. In addition, the scaling error between the base band signal 152 and the digitized signal 155 will vary and thus, the processor 130 must adaptively compensate for this error.

Thus, the present invention can be implemented in a circuit for maintaining linear operation of a power amplifier. The circuit includes a power amplifier, a driver amplifier with variable gain control, a coupler, a voltage detector, and a processor. The power amplifier includes a signal input and a signal output. The variable gain amplifier also includes a signal input and a signal output, as well as a control input. The signal output of the variable gain amplifier is connected to the signal input of the power amplifier and the signal input of the variable gain amplifier receives a modulated signal that has been modulated with a base band signal. The control input of the variable gain amplifier is connected to a control output of the processor. The output signal from the power amplifier is detected through the coupler and the voltage detector and the envelope of the detected signal is provided to the processor.

In operation, the processor receives the detected signal input and after performing timing alignment and level scaling, compares the detected signal to the base band signal. If the difference between the detected signal and the base band signal is outside of a maximum threshold level, then the processor limits the power of the input signal to the power amplifier by adjusting the gain of the variable gain amplifier. If the difference is less than a minimum threshold, then the processor can increase the power of the input signal. However, those skilled in the art will be aware that the input power signal should never be increased beyond the normal level that is calibrated for a given temperature and power supply voltage. In addition, the input power signal should never be increased for linearity reasons beyond the initial power setting for normal or low VSWR conditions. If the difference between the detected signal and the base band signal is between the maximum and minimum threshold levels, then the processor can simply maintain the current power level of the input signal. In addition, the power amplifier can include a control input and the processor can further adjust the gain of the power amplifier, in conjunction with or in lieu of adjusting the gain of the variable gain amplifier.

FIG. 1B is a circuit diagram illustrating an exemplary embodiment of the present invention using a quadrature modulator. As can be seen from the figure, a quadrature modulator 170 is utilized rather than a polar modulator 110 and 115 as shown in FIG. 1A. Alternately, FIG. 1B has scalar 151 in the detected path at the output of the A/D converter 145, instead of at the output of the time shift function 150. Thus, scalar 151 can be used in either the base band signal 152 or detected signal 154 path to scale the amplitude of the signal. The operation of the present invention remains the same with respect to the comparison of the signals.

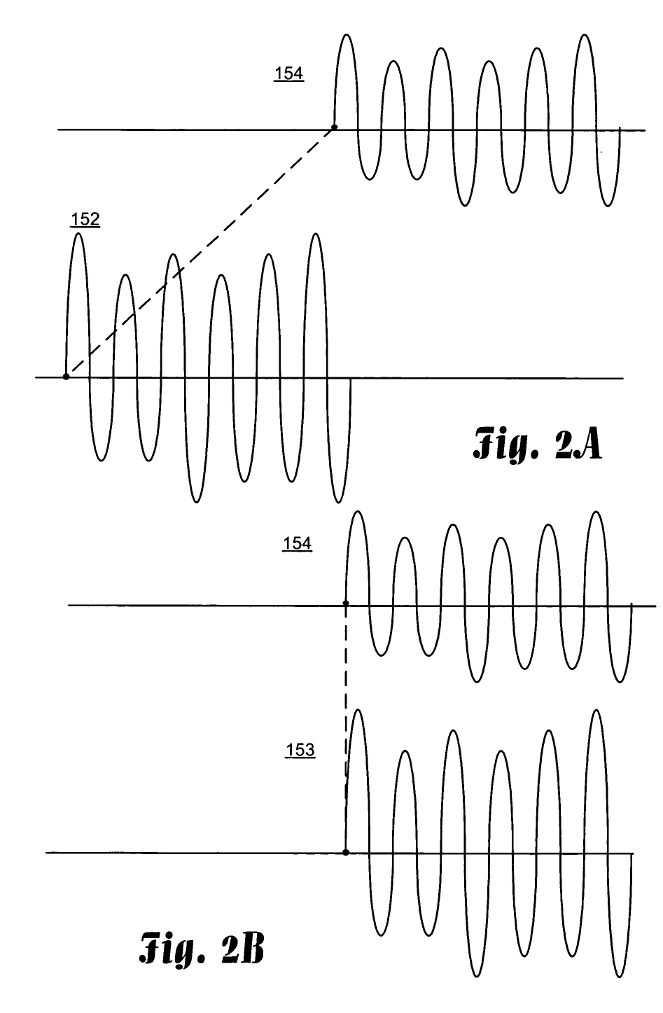

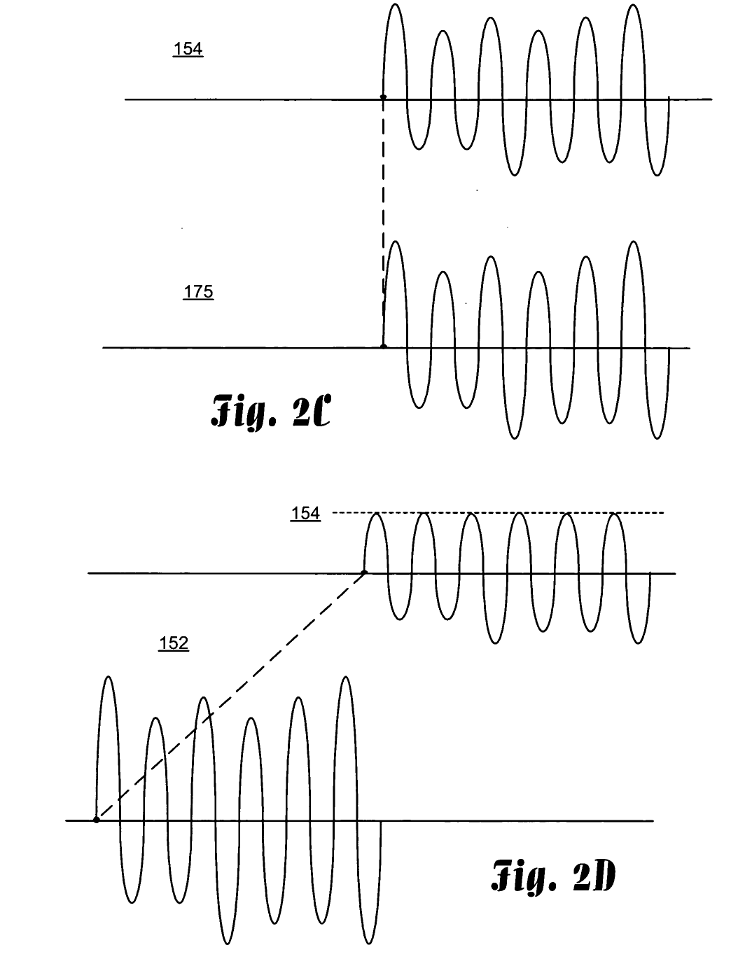

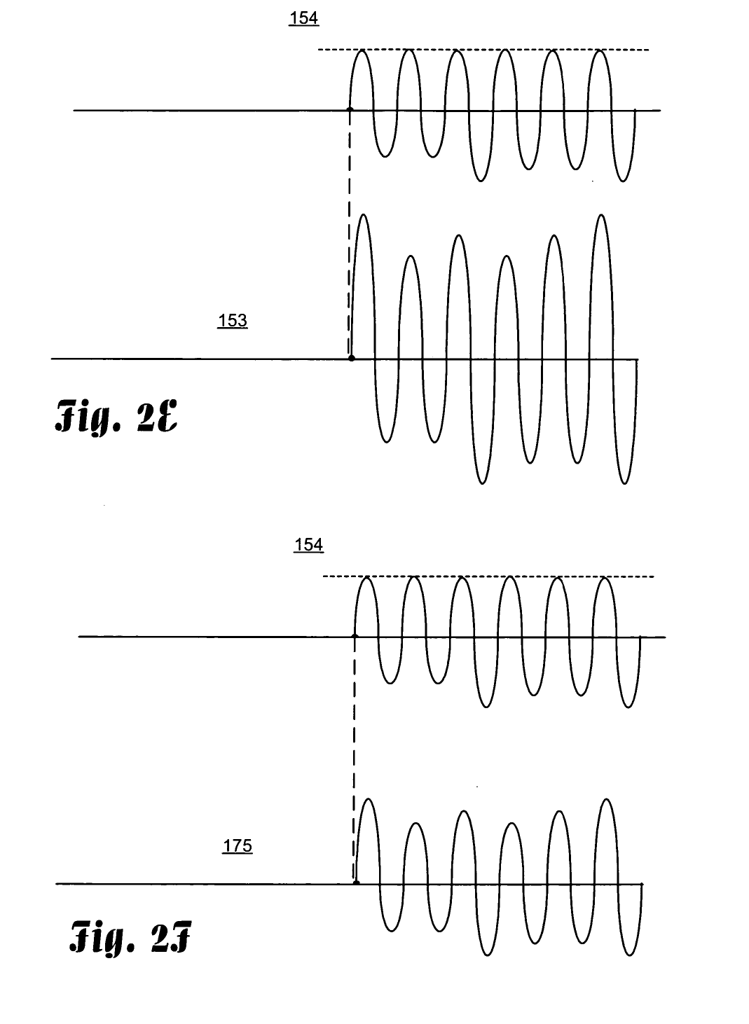

FIG. 2A is a timing diagram illustrating the relationship of the base band signal present at point 152 and the detected output signal 154 when the power amplifier is operating in the linear range. In comparing the amplitude envelopes of the two signals, it is evident that there is no degradation in the linearity of the power amplifier because the envelopes are the same other than being shifted in time and scale. The figure illustrates that the detected signal 154 can be skewed in time and at a different scale than the base band signal present at point 152.

FIG. 2B is a timing diagram illustrating the relationship of the base band signal at point 153 and the detected output signal 154 after the base band signal has been passed through the time shift function 150.

FIG. 2C is a timing diagram illustrating the relationship of the base band signal at point 175 and the detected output signal 154 after the base band signal has been passed through the scalar 151. At this point the two signals are substantially aligned in time and substantially at the same scale.

FIG. 2D is a timing diagram illustrating the relationship of the base band signal present at point 152 and the detected output signal 154 when the power amplifier is not operating in the linear range. In comparing the amplitude of the envelopes of the two signals, it is evident that the detected output signal 154 is being clipped, thereby indicating a degradation in the linearity of the power amplifier. Again, the figure illustrates that the detected signal 154 can be time shifted and at a different scale than the base band signal present at point 152.

FIG. 2E is a timing diagram illustrating the relationship of the base band signal at point 153 and the detected output signal 154 after the base band signal has been passed through the time shift function 150.

FIG. 2F is a timing diagram illustrating the relationship of the base band signal at point 175 and the detected output signal 154 after the base band signal has been passed through the scalar 151. At this point the two signals are substantially aligned in time and substantially at the same scale.

The comparison of the base band signal and the detected output signal 154 is most preferably conducted with digital representations of the signals. In essence, a threshold differentiation level can be established to determine the similarity of the two signals. If the difference between the signals is greater than the threshold differentiation, then the processor will conclude that there is degradation in the linearity of the power amplifier.

The processor 130, by comparing the base band signal 152 and the detected output signal 154, can determine whether there is degradation in the linearity of the power amplifier and if so, make adjustments to remedy the effect. In the illustrated embodiment, the processor 130 can operate to adjust the bias and/or gain of either amplifier 125 or power amplifier 101. By adjusting the gain of amplifier 125, the present invention lowers the input power of the signal being applied to the signal input of the power amplifier 101. In addition, or alternatively, the present invention can adjust the bias or gain of the power amplifier 101 to bring the power amplifier back into the linear region of operation.

In one embodiment of the invention, three threshold levels can be established with regards to the comparison of the detected output signal and the base band signal. The thresholds can be used to identify degrees of differences between the signals. If the difference in the comparison is within a minimum threshold level, this may indicate that the power amplifier is operating well within the linear region and thus, the power level of the input signal can be increased without degrading the linearity of the power amplifier. If the difference in the comparison is within a mid-level threshold level, this may indicate that the power amplifier is operating in the linear region but, only marginally. Thus, the power level of the input signal is maintained. Finally, if the difference in the comparison is outside of a maximum threshold level, the power amplifier is not operating in the linear region and the power level of the input signal must be decreased to restore linearity of the power amplifier.

It should be understood that the references to the threshold levels are relative references. For instance, stating that the difference is outside or greater than a maximum threshold difference is simply used to indicate a relative comparison between the comparison of the output signal level and the input signal level. In other embodiments, inverted logic could be applied and in such a case, the reference of being greater than a threshold would be replaced by being less than the threshold. Thus, the present invention should not be limited to any particular embodiment based on this distinction.

The circuit of FIG. 1 can be incorporated into a variety of transmitting products including, but not limited to, cellular telephones, cellular repeaters, cellular boosters, transmission towers, radio frequency transmitters, etc. The present invention is most applicable within multi-technology and multi-banded mobile stations. Advantageously, the present invention is able to detect when the power amplifier is approaching or entering the non-linear region, and making adjustments to the power level of the input signal to bring the power amplifier back into the linear region. The present invention allows the maintenance of linearity for a power amplifier even in the presence of an unstable or changing load impedance. Thus, even in the absence of an isolator at the output of the power amplifier, the present invention operates to maintain linear operation of the power amplifier.

The present invention can be incorporated into a mobile station for use in a cellular system. In this embodiment, the mobile station will include a power amplifier that receives a signal input from a variable gain amplifier and provides a signal output for transmitting through an antenna. A voltage detector is coupled to the output of the power amplifier for detecting the output signal and obtaining a detected signal output.

The detected signal output is converted to digital through the use of an analog to digital converter that is electrically coupled to the output of the voltage detector. The digital signal is then provided to the processor.

The processor is operative to receive the digital signal, along with the base band signal used to modulate the output signal. The processor correlates the base band signal in time with the digital signal, adaptively adjusts for scaling errors and then compares the envelope of the base band signal with the digital signal. As a result of this comparison, the processor adjusts the gain of the power level of the signal being provided to the power amplifier.

In one embodiment of the invention, the processor adjusts the power level of the input signal by changing the gain of the variable gain amplifier. Thus, if the envelope of the base band signal is significantly different from the detected output signal, the gain can be reduced. If the envelopes are virtually the same, the gain can be increased, however this should only be done when the current power level is below a target power level. This embodiment of the present invention can also make the adjustments to the power level of the input signal based on other factors such as, but not limited to, the internal temperature of the mobile station, the voltage level of a battery supply, and the presence of a substantial VSWR.

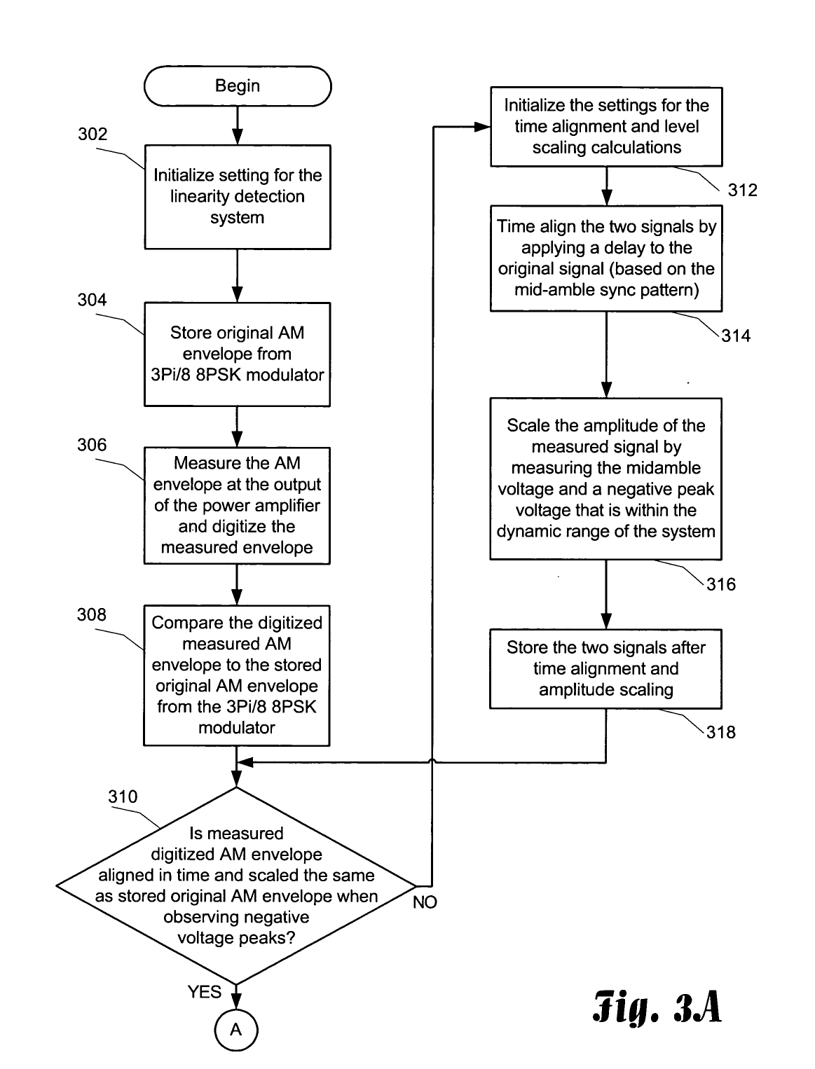

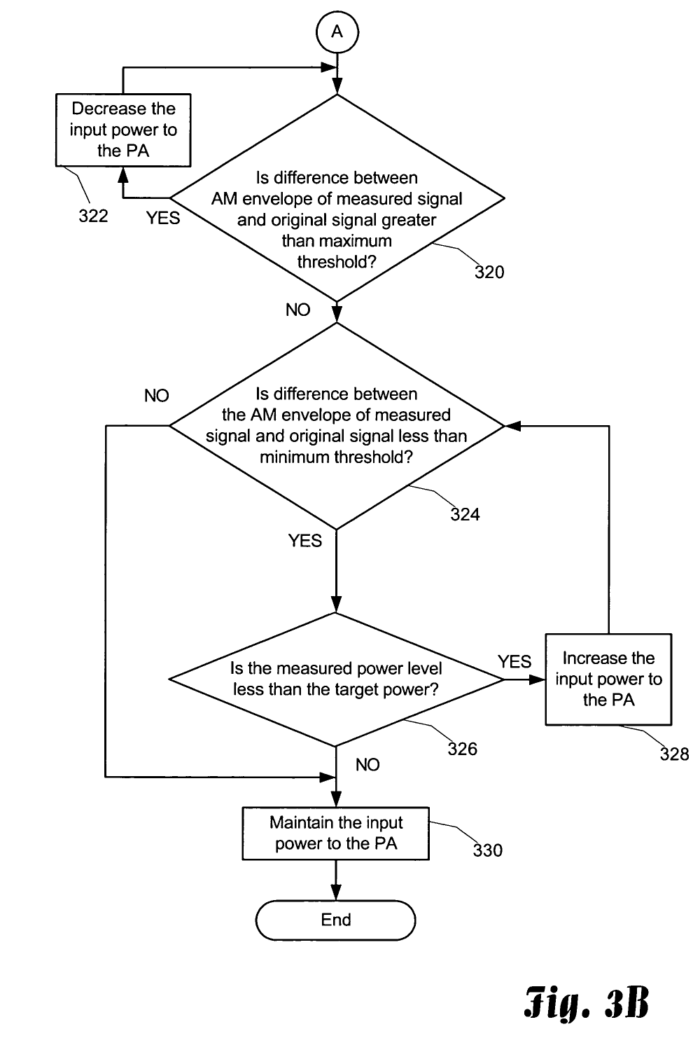

FIGS. 3A-3B are flow diagrams illustrating the operations of the present invention. Upon applying power to the communication device housing a transmitter that incorporates an embodiment of the present invention, the initial settings to the amplifier circuitry are established (step 302). This process involves, among other things, setting the gain of a variable gain amplifier and the power amplifier. In normal transmitter operation, the present invention is operating to detect and maintain operation of the power amplifier within the linear region.

At step 304 the original AM signal is stored and at step 306 the output signal is detected and digitized. This step can be performed in a variety of manners including, but not limited to the coupler and voltage detector described in conjunction with FIG. 1. At step 308 the original AM signal and the detected and digitized output signal are compared. At decision block 310, it is determined whether the two signals are properly aligned time-wise and if there is a scaling error. If the signals are aligned and scaled the same, processing continues at point A in FIG. 3B. Otherwise, processing continues at step 312 where the settings for the time alignment and level scaling calculations are initialized. At step 314, the two signals are time aligned by applying a time shift to the original signal (based on the mid-amble sync pattern). At step 316, the amplitude of the measured signal is scaled by measuring the mid-amble voltage and a negative peak voltage that is within the dynamic range of the system. At step 318, the two signals are then stored and processing returns to decision block 310.

If the two signals are now properly aligned, processing continues at point A of FIG. 3B. At decision block 320, the difference between the AM envelope of the detected and digitized (or measured) signal and the original signal is determined and compared to a threshold value. If the difference is greater than a maximum threshold value, processing continues at step 322 where the power level of the input signal is decreased and the check at decision block 320 is performed again.

If at decision block 320, it is determined that the difference is less than the maximum threshold value, processing continues at decision block 324. At decision block 324 it is determined whether the difference between the AM envelope of the measured signal and the original signal less than a minimum threshold. If the difference is less than the minimum threshold, processing continues at decision block 326.

At decision block 326, the measured power level is compared to a target power level. If the measured power level is less than the target power, processing continues at block 328 where the input power to the power amplifier is increased. Otherwise, the input power is simply maintained at the present value. Processing can then return to step 302 in FIG. 3A.

In one embodiment, threshold levels can be established. The threshold levels represent varying degrees in the similarity of the signal envelopes. For instance, very similar envelopes will have a minimum threshold level and dissimilar envelopes will have a maximum threshold level. If the results of the comparison exceed the maximum threshold level, the power level of the input signal should be decreased. If the results of the comparison are within the minimum threshold level, then the power level of the input signal can be increased. If the results of the comparison are between the maximum and minimum threshold values, then the power level of the input signal should be maintained.

In addition, the signal comparison aspect of the present invention can be implemented within a single processor, such as the base band processor resident in cellular telephone or mobile station designs. The processing capability of such processors enables the comparison and analysis to be accomplished in a cost effective and time efficient manner.

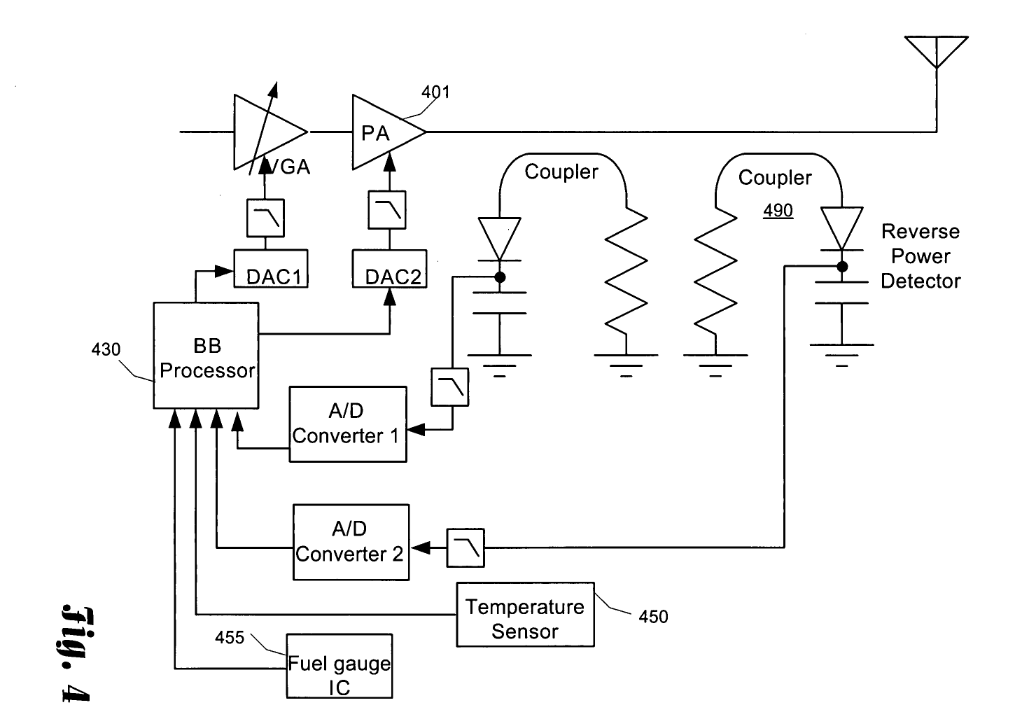

FIG. 4 is a circuit diagram illustrating the incorporation of temperature and voltage compensation into present invention. By using temperature and/or voltage compensation, the accuracy of the operation of the present invention in adjusting the linearity of the power amplifier can be improved. Based on the temperature of the power amplifier sensed by the temperature sensor 450 and/or the level of the voltage supplied to the power supply input of the power amplifier as detected by the fuel gauge 455 (or voltage level sensor), the processor 430 can add an offset to the power amplifier 401 input power or to the bias control input to compensate for the affects that these variables have on the linearity of the power amplifier. In addition, the circuit in FIG. 4 illustrates the use of an additional detector 490 at the power amplifier 401 output. The additional detector 490 operates to detect the reverse power in extreme VSWR conditions. This information can be used by the processor 430 to further aid in calculating the linearity compensation requirements. For example, under certain cases, if the VSWR detected by the additional detector 490 is high, the processor 430 can increase the power amplifier bias to operate the power amplifier in a more linear mode and thus compensate for the effects of VSWR. Typically this is true when the battery or supply voltage is at a sufficient level. Thus, when performing this operation, the voltage level should be monitored to ensure the supply is sufficient, or the operation can be limited to only when an external power supply is connected, such as a car charger. Thus, the use of the additional detector 490 provides even more feedback information to the processor 430, that the processor can use in determining if the power amplifier 401 is operating in the linear region. It should be noted that notwithstanding the linear operation of the amplifier, the output power level at the antenna is still subjected to maximum requirements established by the specification and thus, should not exceed the desired power level.

The present invention has been described using detailed descriptions of embodiments thereof that are provided by way of example and are not intended to limit the scope of the invention. The described embodiments comprise different features, not all of which are required in all embodiments of the invention. Some embodiments of the present invention utilize only some of the features or possible combinations of the features. Variations of embodiments of the present invention that are described and embodiments of the present invention comprising different combinations of features noted in the described embodiments will occur to persons of the art. The scope of the invention is limited only by the following claims.

1. A method of detecting linear operation in a power amplifier, the power amplifier being operative to amplify an input signal for transmission, the method comprising the steps of:
detecting the output signal of the power amplifier, the output signal having been modulated with a base band signal;
converting the detected output signal into a digital signal;
comparing the envelope of the detected and converted output signal to the envelope of the base band signal; and
decreasing the input power level of the input signal if the difference between the envelope of the detected and converted output signal and the envelope of the base band signal is beyond a first threshold level.

2. The method of claim 1, further comprising the step of time aligning the detected and converted output signal with the base band signal.

3. The method of claim 1, wherein the input signal is provided to the power amplifier through a variable gain amplifier, and the step of decreasing the input power level of the input signal comprises decreasing the gain of the variable gain amplifier.

4. The method of claim 1, further comprising the step of increasing the input power level of the input signal if the difference between the envelope of the detected and converted signal and the envelope of the base band signal is not beyond a second threshold level.

5. The method of claim 1, further comprising the step of maintaining the input power level of the input signal if the difference between the envelope of the detected and converted signal and the envelope of the base band signal is between the second threshold level and the first threshold level.

6. A circuit for maintaining linear operation of a power amplifier, the circuit comprising the components of:
a power amplifier, a variable gain amplifier, a coupler, a voltage detector, and a processor,
the power amplifier having a signal input and a signal output;
the variable gain amplifier having a signal input, a signal output, and a control input, the signal output of the variable gain amplifier being electrically coupled to the signal input of the power amplifier, the signal input of the variable gain amplifier receiving a modulated signal that has been modulated with a base band signal, the control input of the variable gain amplifier being connected to a first control output of the processor,
the coupler being electrically coupled to the signal output of the power amplifier and operative, in cooperation with the voltage detector, to detect the envelope of an output signal at the signal output of the power amplifier and provide the detected envelope to a detected signal input of the processor;
the processor, being operative to:
receive the detected signal input and compare the detected signal input to the base band signal;
adjust the first control output of the processor to limit the gain of the variable gain amplifier if the detected signal input is beyond a first threshold level in comparison with the base band signal.

7. The circuit of claim 6, wherein if the detected signal input is within a second threshold level in comparison with the base band signal and the output power is below a target threshold, the processor is further operative to adjust the first control output of the processor to increase the gain of the variable gain amplifier.

8. The circuit of claim 7, wherein if the detected signal input is between the first threshold level and the second threshold level in comparison with the base band signal, the processor is further operative to maintain the value of the first control output of the processor and thereby maintain the gain of the variable gain amplifier.

9. The circuit of claim 6, wherein if the detected signal input is within the first threshold level in comparison with the base band signal, the processor is further operative to maintain the value of the first control output of the processor and thereby maintain the gain of the variable gain amplifier.

10. The circuit of claim 6, wherein the power amplifier further includes a control input and the processor further includes a second control output that is electrically coupled to the control input of the power amplifier and initially set to a normal value and, if the detected signal input is beyond of the first threshold level, the processor is further operative to adjust the second control output to change the bias of the power amplifier to improve the linearity and, if the detected signal input is within a second threshold level, to adjust the second control output to change the bias of the power amplifier towards the normal value if the bias of the power amplifier has been previous changed.

11. A mobile station for use in a cellular system, the mobile station comprising:
a power amplifier having a signal input received from a variable gain amplifier and a signal output for transmitting through an antenna;
a voltage detector coupled to the output of the power amplifier for detecting the output signal and obtaining a detected signal output;
an analog to digital converter electrically coupled to the output of the voltage detector for receiving the detected signal and for converting the detected signal from analog to a digital signal and providing the digital signal to a digital output;
a processor coupled to the digital output of the analog to digital converter for receiving the digital signal, the processor being operative to:
receive a base band signal originally used to modulate the detected output signal;
correlate the base band signal with the digital signal;
compare the envelope of the base band signal with the digital signal; and
adjust the gain of the variable gain amplifier in accordance with the results of the comparison.

12. The mobile station of claim 11, wherein the processor is operative to adjust the gain of the variable gain amplifier by decreasing the gain if the comparison is beyond a maximum threshold of difference.

13. The mobile station of claim 12, wherein the processor is further operative to adjust the gain of the variable gain amplifier by increasing the gain if the comparison is within a minimum threshold difference.

14. The mobile station of claim 13, wherein the processor is further operative to maintain the gain of the variable gain amplifier if the comparison is between the minimum threshold and the maximum threshold difference.

15. The mobile station of claim 11, further comprising a temperature sensor and, the processor is further operative to adjust the gain of the variable gain amplifier in accordance with the comparison and the temperature reading of the sensor.

16. The mobile station of claim 15, further comprising a voltage sensor for measuring the voltage level of a source providing power to the mobile station and, the processor is further operative to adjust the gain of the variable gain amplifier in accordance with the comparison, the temperature reading of the sensor and the level reading of the voltage sensor.

17. The mobile station of claim 16, further comprising a reverse power detector for detecting a voltage standing wave ratio and, the processor is further operative to adjust the gain of the variable gain amplifier in accordance with the comparison, the temperature reading of the sensor, the level reading of the voltage sensor and the voltage standing wave ratio.

18. The mobile station of claim 11, further comprising a voltage sensor for measuring the voltage level of a source providing power to the mobile station and, the processor is further operative to adjust the gain of the variable gain amplifier in accordance with the comparison and the level reading of the voltage sensor.

19. The mobile station of claim 11, further comprising a reverse power detector for detecting a voltage standing wave ratio and, the processor is further operative to adjust the gain of the variable gain amplifier in accordance with the value of the comparison and the voltage standing wave ratio.

20. The mobile station of claim 11, wherein the base band signal is correlated with the digital signal by compensating for timing shift and the amplitude scaling.
